(19) United States
(12) Patent Application Publication
(10) Pub. No.: US 2015/0221578 A1
(43) Pub. Date: Aug. 6, 2015

(54) SEMICONDUCTOR PACKAGE AND METHOD FOR PRODUCING A SEMICONDUCTOR

(71) Applicant: Infineon Technologies AG, Neubiberg (DE)

(72) Inventor: Joachim MAHLER, Regensburg (DE)

(73) Assignee: Infineon Technologies AG, Neubiberg (DE)

(21) Appl. No.: 14/173,141

(22) Filed: Feb. 5, 2014

(51) Int. Cl. H01L 23/433; H01L 21/56; H01L 23/495; H01L 23/29; H01L 23/31; H01L 23/498

(52) U.S. Cl. CPC H01L 23/4334; H01L 23/3107; H01L 23/49838; H01L 23/49541; H01L 23/295; H01L 21/565

(57) ABSTRACT

A device includes a die and at least one of an encapsulant at least partly encapsulating the die and a carrier to which the die is attached. The at least one of the encapsulant and the carrier includes a thermoplastic polymer that includes metallic particles.

### TECHNICAL FIELD

The disclosure relates to semiconductor packages. The disclosure further relates to methods for producing semiconductor packages.

### BACKGROUND

A semiconductor package may be configured to protect a die from physical damage. In addition, the semiconductor package can protect the die from environmental influences such as humidity or chemical surroundings. A semiconductor package may be produced by mounting a die onto a carrier or a leadframe and molding an encapsulant material around the mounted die. A thermal conductivity of encapsulants used for semiconductor packages may be less or equal to about 10 W/(m*K).

In operation, a die may produce heat that should be evacuated to ensure reliability of the die. Especially for new chip technologies, such as e.g. dies based on gallium nitride (GaN), the problem of dies heating themselves may limit their performance in power applications. Device heating may thus become a problem for reliable power electronic devices. The usual thermal conductivity of encapsulants as previously mentioned may be insufficient to transport the heat away from the chip.

### BRIEF DESCRIPTION OF THE DRAWINGS

The accompanying drawings are included to provide a further understanding of examples and are incorporated in and constitute a part of this description. The drawings illustrate examples and together with the description serve to explain principles of examples. Other examples and many of the intended advantages of examples will be readily appreciated as they become better understood by reference to the following detailed description.

FIG. 1 illustrates a semiconductor package encapsulating a die.

FIG. 2 illustrates a die arranged over a carrier.

FIG. 3 shows a cross-sectional view of a die placed partly into a carrier.

FIG. 4 schematically illustrates a first encapsulant material.

FIG. 5 schematically illustrates a second encapsulant material.

FIG. 6 schematically illustrates a third encapsulant material.

FIG. 7 schematically illustrates a fourth encapsulant material.

FIG. 8 schematically illustrates a semiconductor package including a separate electrical contact.

FIG. 9 schematically illustrates an encapsulant with metallic particles forming a metallic surface over a surface of the encapsulant.

FIGS. 10A to 10D illustrate a method for producing semiconductor packages.

FIG. 11 is a flow diagram illustrating a method for producing a semiconductor package.

### DETAILED DESCRIPTION

In the following, examples are described with reference to the drawings, wherein like reference numerals are generally utilized to refer to like elements throughout. In the following description, for purposes of explanation, numerous specific details are set forth in order to provide a thorough understanding of one or more aspects of examples. However, it may be evident to a person skilled in the art that one or more aspects of the examples may be practiced with a lesser degree of these specific details. The following description is therefore not to be taken in a limiting sense, and the scope of protection is defined by the appended claims.

The various aspects summarized may be embodied in various forms. The following description shows by way of illustration various combinations and configurations in which the aspects may be practiced. It is understood that the described aspects and/or examples are merely examples and that other aspects and/or examples may be utilized and structural and functional modifications may be made without departing from the scope of the present disclosure. In addition, while a particular feature or aspect of an example may be disclosed with respect to only one of several implementations, such feature or aspect may be combined with one or more other features or aspects of the other implementations as it may be desired and advantageous for any given or particular application.

It is to be appreciated that features and/or elements depicted herein may be illustrated with particular dimensions relative to each other for purposes of simplicity and ease of understanding. Actual dimensions of the features and/or elements may differ from that illustrated herein.

As employed in this specification, the terms “connected”, “coupled”, “electrically connected” and/or “electrically coupled” are not meant to necessarily mean that elements must be directly connected or coupled together. Intervening elements may be provided between “connected”, “coupled”, “electrically connected” or “electrically coupled” elements.

The word “over” used with regard to e.g. a material layer formed or located “over” a surface of an object may be used herein to mean that the material layer may be located (e.g. formed, deposited, etc.) “directly on”, e.g. in direct contact with, the implied surface. The word “over” used with regard to e.g. a material layer formed or located “over” a surface may also be used herein to mean that the material layer may be located (e.g. formed, deposited, etc.) “indirectly on” the implied surface with e.g. one or more additional layers being arranged between the implied surface and the material layer.

To the extent that the terms “include”, “have”, “with” or other variants thereof are used in either the detailed description or the claims, such terms are intended to be inclusive in a manner similar to the term “comprise”. Also, the term “exemplary” is merely meant as an example, rather than the best or optimal.

Semiconductor packages and methods for manufacturing semiconductor packages are described herein. Comments made in connections with the described semiconductor packages may also hold true for corresponding methods and vice versa. For example, if a specific component or specific encapsulant material of a semiconductor package is described, a corresponding method for manufacturing the semiconductor package may include an act of providing the corresponding encapsulant material in a suitable manner, even if such an act is not explicitly described or illustrated in the figures. Similarly, the method may include an act of providing the specific component.

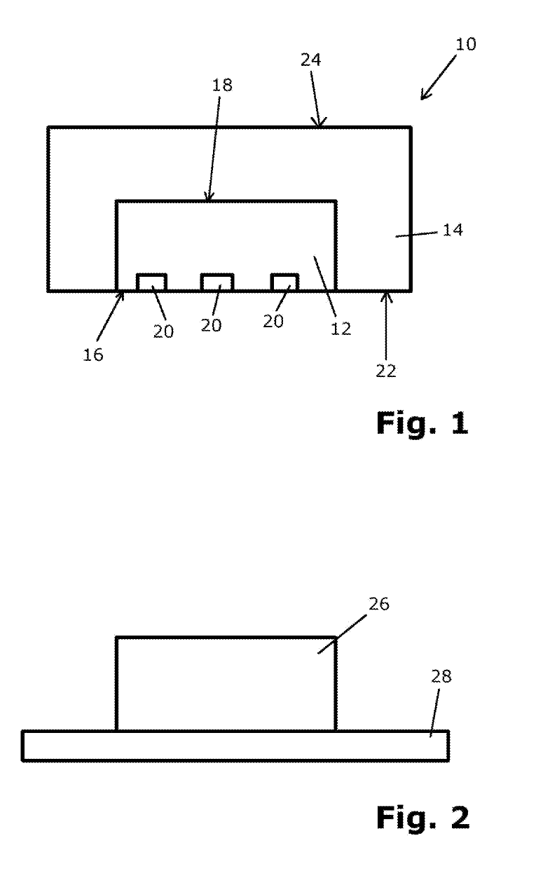

FIG. 1 shows a semiconductor package 10 including a die 12 and an encapsulant 14. In the following, the expressions “die”, “chip” and “semiconductor chip” may be used interchangeably for designating similar entities. The die 12 may include an active surface 16 and a backside surface 18. The active surface 16 may include an integrated circuit. In addition, the active side 16 can include electrical contacts 20. The backside surface 18 may include a metallic surface, i.e. a backside metallization.

In one example, the die 12 may be a silicon die. In a further example, the die 12 may correspond to a gallium nitride die. Other chip materials such as e.g. gallium arsenide may be possible as well. The disclosure described herein may be particularly suited for power devices generating an increased amount of heat. The die 12 may be a vertical component such as e.g. a vertical power transistor. The semiconductor package 10 may have a first main surface 22 and a second main surface 24 opposite the first main surface 22. The first main surface 22 can be coplanar to the active surface 16 of the die 12. The semiconductor package 10 may be mounted onto a carrier such as e.g. a Printed Circuit Board (PCB) with the main surface 22 facing the PCB. Thus, electrical contacts 20 can be soldered to corresponding contact pads on the PCB.

In further examples the die 12 may be completely encapsulated by the encapsulant 14. In this case, electrical lines or electrical connections may be provided which electrically connect electrical contacts over or on the die with electrical contacts over or on an outer surface of the semiconductor package.

An encapsulant material that may be suitably used in the semiconductor package 10 will be further explained with reference to FIGS. 4 to 7.

FIG. 2 shows a die 26 that may be mounted onto a carrier 28. The carrier 28 may be formed by a similar encapsulant material 14 as used for the semiconductor package 10 of FIG. 1 and explained with reference to FIGS. 4 to 7.

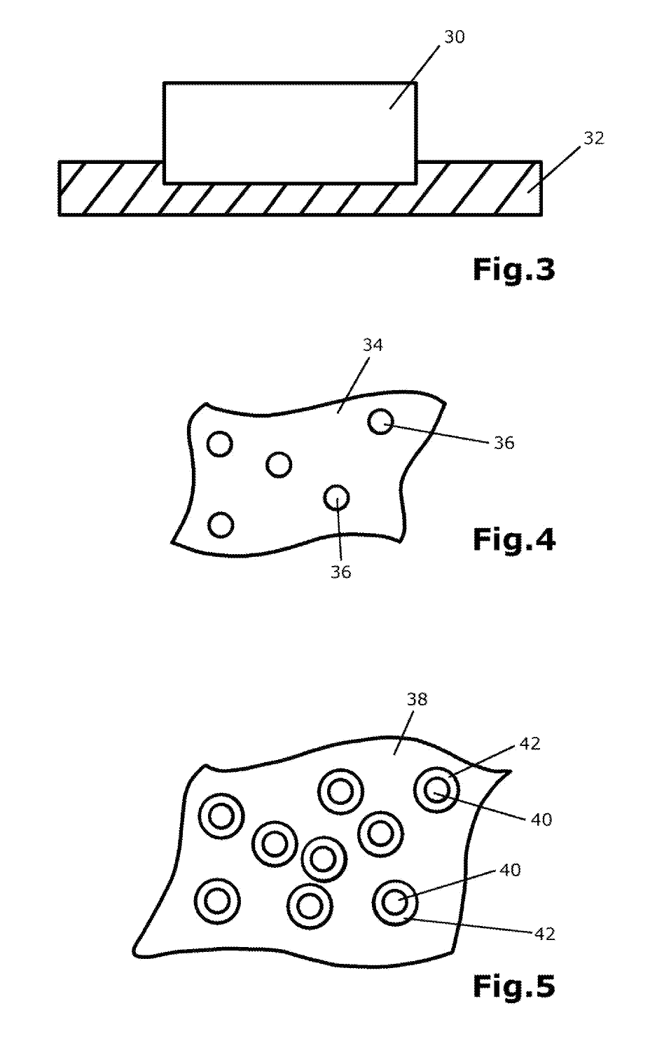

FIG. 3 illustrates a semiconductor die 30 that may be mounted onto a carrier 32. In this example, the die 30 may be partly inserted into the carrier 32 as can be seen in the cross-sectional view of FIG. 3. In other words, the carrier 32 may partly enclose side walls of the die 30. The carrier 32 may be formed by a similar encapsulant material 14 as carrier 28 and as used in semiconductor package 10.

The encapsulant materials that may be used for encapsulating the die 12 and for forming the carrier 28 and the carrier 32 will be further explained in the following. The encapsulant 14 and the carriers 28 and 32 can include a polymer that may include metallic particles. FIG. 4 schematically illustrates a polymer 34 including metallic particles 36. The polymer may be a thermoplastic polymer or a duroplastic or in other words a thermosetting polymer.

A thermoplastic material may include amorphous polymers and/or crystalline polymers. The thermoplastic polymers may be at least one of e.g. polyether ether ketone (PEEK), polyamide-imide (PAI), polyethersulfone (PES), polysulfone (PSU), polystyrene (PS), polyphenylene sulfide (PPS) and a liquid-crystal polymer (LCP). At room temperature, thermoplastic polymers may be hard and may not necessarily require a cure. Thermoplastic polymers can be processed by raising a temperature above a particular value at which the material becomes soft or liquid. This temperature may be called glass transition temperature for an amorphous thermoplastic polymer or melting temperature for a crystalline or semi-crystalline thermoplastic material. The glass transition temperature for the amorphous thermoplastics or the melting temperature for the crystalline or semi-crystalline thermoplastics that may be used as encapsulant/carrier material may be equal or greater than about 260° C. With a glass transition temperature or melting temperature above 260° C., the semiconductor package/the carrier does not necessarily become soft during usual processing steps as e.g. soldering the semiconductor package onto a PCB.

A thermoplastic material may be heated more than once. Each time a thermoplastic polymer is heated above its glass transition or melting temperature, it may become soft and it may harden when the temperature falls below. In other words, the step of softening and hardening is reversible.

A thermoset or thermosetting polymer may include at least one of e.g. epoxies, acrylic resins, polyimides and cyanate esters. A thermosetting polymer needs to be exposed to an elevated cure temperature to cure or in other words to induce cross-linking chemical reactions between monomers. Once the thermosetting material is cured, it cannot be re-softened. Thermosetting material may also not necessarily be used as an adhesive. It may be impossible with a thermosetting material to place, for example, a die into a carrier as explained with reference to FIG. 3.

Polymers may show a reduced thermal conductivity. In particular, the polymers may have a thermal conductivity of about 0.1 W/m*K to about 0.5 W/m*K. For obtaining an increased thermal conductivity, a polymer may be filled with metallic particles. Metals may have a thermal conductivity between about 10 W/m*K and about 400 W/m*K. By filling the polymer with metallic particles, the thermal conductivity can be adjusted.

The thermal conductivity may be a function of a volumetric fill factor of the metallic particles in the polymer. The volumetric fill factor of the metallic particles can be chosen to provide a thermal conductivity of at least about 20 W/(m*K). Metallic filler particles may be of any metal. For example, a metal having a high thermal conductivity may be copper. Hence, copper may be used for filler particles. The thermal conductivity may increase proportionally with the fill factor.

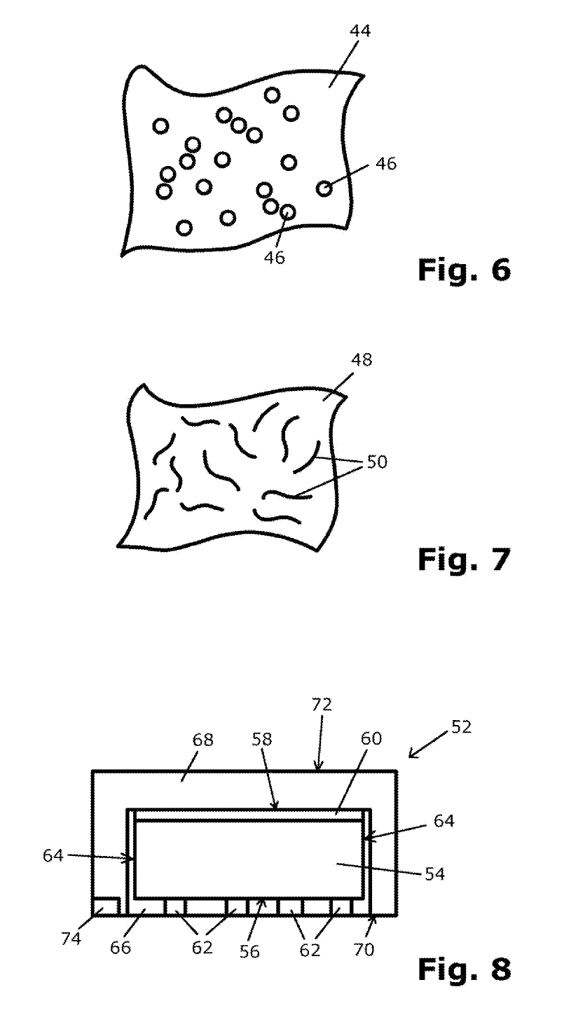

Polymers may be electrically insulating while metal particles may be electrically conductive. Metallic filler particles in a polymer may provide electrical conductivity to the filled material. The electrical conductivity of the filled polymer does not necessarily increase proportionally with the fill factor, but may rises rather abruptly at a so-called percolation threshold. The percolation threshold may occur when the fill factor is high enough for metallic particles to touch each other and thus provide conductive paths (see FIG. 6). In the examples of FIGS. 1 to 3, electrical conductivity of the encapsulant may be advantageous and the volumetric fill factor can be chosen to be above the percolation threshold. With a high volumetric fill factor the thermal conductivity may be high as well. On the other hand, in examples as shown in FIGS. 1 to 3, electrical conductivity of the encapsulant can be undesired and the volumetric fill factor can be chosen to lie below the percolation threshold. With a lower volumetric fill factor the thermal conductivity may be lower as well. The volumetric fill factor of the metallic particles in the thermoplastic polymer may be between about 20% and about 90%.

The metallic particles 36 may be uncoated. Therefore, the fill factor should remain under the percolation threshold if electrical conductivity is to be avoided. The metallic particles may be coated with an insulator, i.e. a material having a very low electrical conductivity up to an electrical conductivity of zero.

FIG. 5 schematically illustrates an encapsulant including a polymer 38 and metallic particles 40. The metallic particles 40 may be coated with an electrically insulating material 42. For example, the electrically insulating material may be or may include an oxide of the metal of the particles 40. Coating of the metallic particles 40 may have the advantage that, even with an increased volumetric fill factor, the material does not necessarily become electrically conductive. The volumetric fill factor of the metallic particles in the polymer may be between about 20% and about 90%. Even with a fill factor near or above 90%, the filled polymer does not necessarily become electrically conductive. Hence, a thermal conductivity may be increased without an electrical conductivity of the filled polymer.

Coating of the metallic particles may be effectuated by emerging the metallic particles into an ammonium sulfate (NH₄) solution. Afterwards the particles may be heated to about 200° C. The result may be a coating including an oxide of the metal, for example copper oxide.

FIG. 6 shows an encapsulant polymer 44 including non-coated metallic particles 46 with a high fill factor above the percolation threshold. The metallic particles may contact each other, thus forming electrically conductive paths. To the contrary, coated particles as shown in FIG. 5 do not form electrically conductive paths even if they contact each other because the insulating coating layer insulates the metallic particles from each other. Thus, there is no electric conductivity. When using coated metallic particles, the fill factor may be increased to achieve a higher thermal conductivity without having an undesired electrical conductivity.

FIGS. 4 to 6 schematically illustrate the metallic particles as spherical parts. In further example, the metallic particles may have arbitrary different forms, for example a tile form or an elliptical form. For example, the metal particles may have dimension between about 75 μm (micrometer) and about 100 μm (micrometer).

FIG. 7 shows an example with a polymer 48 including metallic particles in the form of metallic fibers. These fibers may be coated or uncoated. The fibers may have a thickness of about 30 μm (micrometer) to about 120 μm (micrometer).

Thermoplastic polymers may e.g. be formed by injection molding. As the thermoplastic material allows re-heating several times without a cure process, it may be possible (see e.g. FIG. 3) to injection mold a carrier such as e.g. the carrier 32 in a mold and to place the chip or several chips onto or over the carrier while the carrier may be still soft or again softened. The die can be inserted into the carrier with a defined pressure such that the carrier may partly enclose side walls of the die. Afterwards the carrier may be cooled down and the die may stick to the carrier without the necessity of any adhesives. In other words, the thermoplastic polymer used as encapsulant and/or carrier material may have the function of an adhesive.

Filling of the metallic particles into the polymer may be performed by compounding. Compounding means to mix all ingredients together in a way that those ingredients are randomly distributed inside the compound.

FIG. 8 shows a semiconductor package 52 including a die 54. The die 54 may have an active surface 56 and a back side surface 58 opposite the active surface 56. The back side surface 58 may be covered by a back side metallization 60. The active surface 56 may include electrical contacts 62. The active surface 56 and the back side surface 58 can be connected with each other by side surfaces 64 of the die 54. A dielectric 66 may cover the side surfaces 64 of the die 54 and may insulate the electrical contacts 62 from each other. An encapsulant 68 may be formed, for example by injection molding a thermoplastic polymer filled with metal particles around the side surfaces and the back side surface of the die 54.

The semiconductor package 52 may include a first surface 70 and a second surface 72 opposite the first surface 70. The first surface 70 may be coplanar to a surface formed by the dielectric in-between the electrical contacts 62. The semiconductor package 52 can include a further electrical contact 74 that may be inserted in the encapsulant material 68. The supplementary electrical contact 74 can be formed over the first surface 70 of the semiconductor package 52.

In the example of FIG. 8 an electrical conductivity of the encapsulant 68 may be advantageously used. The encapsulant 68 may be a thermoplastic polymer filled with uncoated metallic particles. The volumetric fill factor can be chosen to provide an electrical conductivity of at least about 10⁶ S/m. It can then be the encapsulant 68 itself which may provide an electrical connection between the back side metallization 60 and the electrical contact 74. In addition, the metallic particles may provide an electromagnetic shielding. The semiconductor package 52 as shown in FIG. 8 may be directly soldered to a PCB wherein the electrical contact 74 may provide a mass contact.

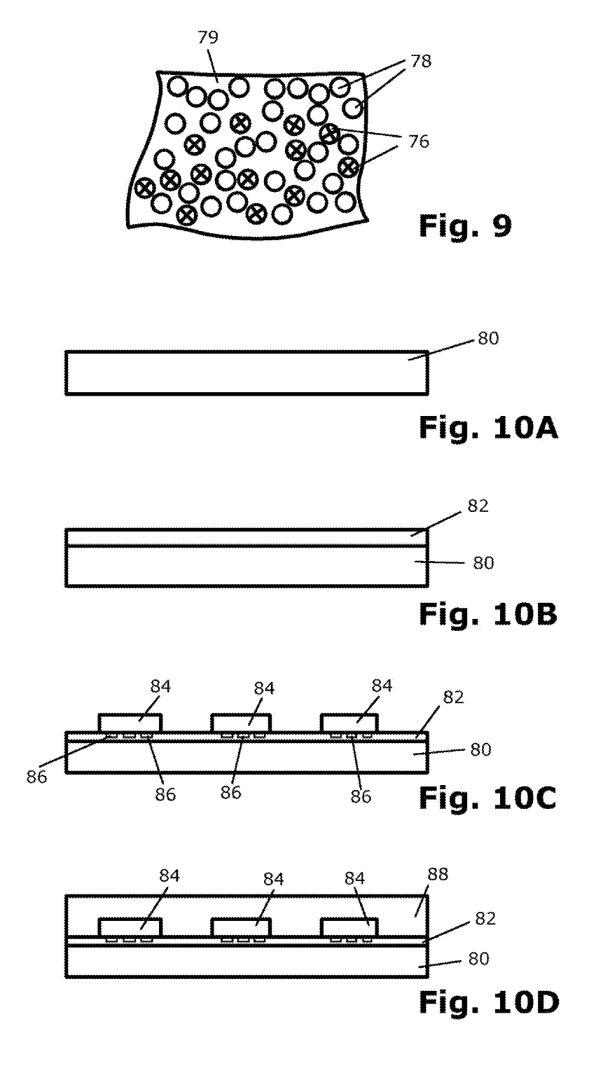

FIG. 9 shows a further example of an encapsulant material that may be used in a semiconductor package. The illustration of FIG. 9 differs from the illustrations in FIGS. 4 to 7 in that the polymer material is also shown in the form of circles to better visualize a distribution of polymer and metal. In FIG. 9 circles 76 bearing a cross represent polymer particles while circles 78 without any cross represent metallic particles. In this example, a semiconductor package may be formed as explained with reference to FIGS. 1 and 8. After injection molding a thermoplastic polymer filled with metallic particles (or after transfer molding a thermosetting polymer filled with metallic particles), a homogenous distribution of metallic particles and polymer particles may be achieved. The metallic particles may be coated or uncoated.

In one example, the volumetric fill factor may be chosen to rest below the percolation threshold so as to have an encapsulant material which is not electrically conductive. In a further example, the chosen material may include coated metallic particles such that the volume fill factor may be increased leading to a higher thermal conductivity while the encapsulant is still not electrically conductive.

After forming the semiconductor package, the package may be selectively heated in certain regions. The heating may e.g. be achieved by means of a laser irradiating regions of a package surface. The heating may be effectuated in a way to burn polymer particles. After the polymer particles are burned, only metallic particles remain. In the case of coated metal particles the heating is further effectuated in a way to melt the coating. In FIG. 9, the upper part of the encapsulant has been heated. Only metallic particles remain near the surface forming a metallic region 79. The metallic region 79 may be formed in immediate vicinity to a backside surface of the encapsulated die. The heating may be chosen to melt the metallic particles leading to an interconnection of metallic particles. In one example, the metallic region 79 may be electro-plated or galvanized afterwards to obtain a thicker conductive region.

In a further example, a side surface and an upper surface of the semiconductor package may be heated/irradiated. Thereby, an electrical connection may be formed between an upper surface of the package to a lower surface of the package. A metallic region may be formed in immediate vicinity to the back side surface of the encapsulated die. As shown in FIG. 8 an electrical connection between the back side surface and a supplementary electrical contact 74 may be achieved while maintaining an encapsulant which is in general not electrically conductive.

FIGS. 10A to 10D illustrate a method of producing semiconductor package.

In FIG. 10A, a temporary carrier 80 may be provided.

In FIG. 10B, an adhesive 82 may be provided over the temporary carrier 80. In one example, the adhesive 82 may correspond to an adhesive film. The adhesive 82 may also be provided over the carrier 80 by e.g. dispensing, jetting, spraying, spinning, etc.

In FIG. 10C, chips or dies 84 may be placed over the adhesive 82. The dies 84 that are to be encapsulated may have been obtained from one single wafer or from different wafers. The wafer or wafers may have been cut into separate chips before, i.e. the chips may have been singulated. The dies may be placed with their respective active sides over the adhesive 82. In the example of FIG. 10C, three dies 84 having electrical contacts 86 are partly immerged in the adhesive film 82. In one example, a sawing film over a wafer may be used and the expanded wafer may be mounted with the sawing film onto the temporary carrier 80.

In FIG. 10D, the temporary carrier 80 with the dies 84 adhered to may then be placed into a mold. An encapsulant material 88 as explained with reference to FIGS. 4 to 7 may be molded onto and around the dies 84. If the encapsulant material 88 includes a thermoplastic polymer, it may be injection molded onto and around the dies 84. If the encapsulant material 88 includes a thermosetting polymer, the encapsulant may be transfer molded. FIG. 10D illustrates the carrier 80 including the encapsulated dies 84. The encapsulated dies 84 may then be separated into individual semiconductor packages. In another example, the mold may include separate molds for each package. The temporary carrier may be removed before the separation into individual semiconductor packages. Alternatively, the temporary carrier may be removed after the separation into individual semiconductor packages.

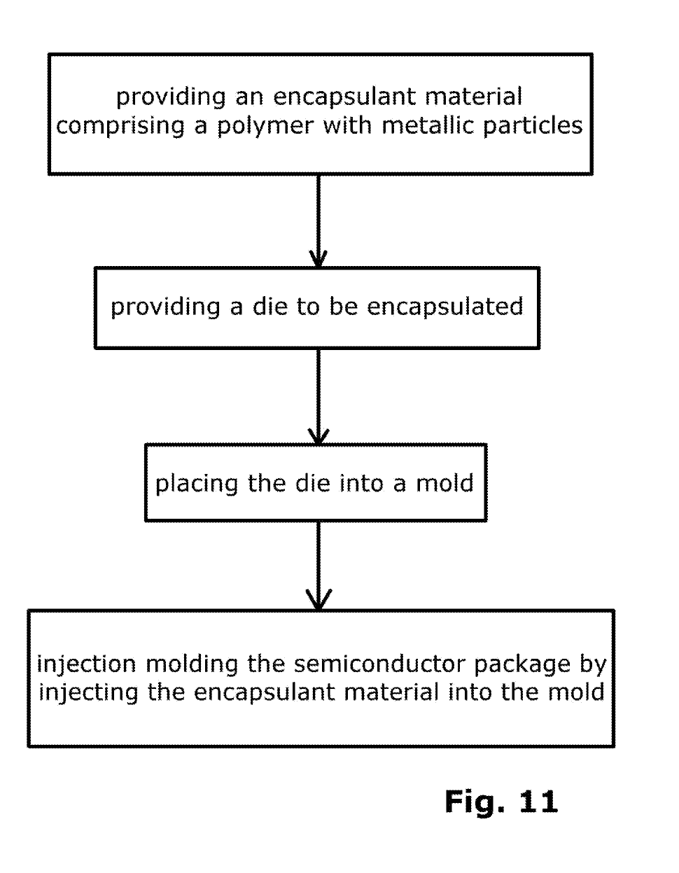

FIG. 11 shows a flow diagram illustrating a method for producing a semiconductor package. In one act, an encapsulating material may be provided that may include a thermoplastic polymer with metallic particles. The encapsulating material may include a thermoplastic polymer filled with uncoated metallic particles. The encapsulating material may include a thermoplastic polymer filled with metallic particles that may be coated with an electrically insulating material. In a further act, a die may be provided that is to be encapsulated. It may be possible to encapsulate a single die or to encapsulate a plurality of dies in one mold act. In a further act, the die or the dies may be placed into a mold. In a further act, the thermoplastic polymer may be injection molded to form the semiconductor package. In injection molding, the encapsulant material that may be a thermoplastic material is injected into the mold.

In one example, first a carrier may be injection molded in a mold form, wherein the carrier includes a thermoplastic polymer. Subsequently, a die or dies may be set into the carrier while the carrier is soft such that the die or dies adhere to the carrier without the necessity of any adhesive. The semiconductor package can then be finished by further injecting encapsulant material. The encapsulant material may attach or adhere to the carrier and to the die. The carrier can include metal particles with another volumetric fill factor than the finishing encapsulant material. It may be also possible to have the carrier including a thermoplastic polymer filled with metal particles with a fill factor of metal particles such that the carrier may be electrically conductive while the remaining semiconductor package encapsulant may be thermally conductive without being electrically conductive. This can be achieved by adjusting the fill factor accordingly or by using coated metal particles for the further encapsulant material.

In one example, a surface of an encapsulant, which is not electrically conductive, may be selectively heated to burn polymer particles to augment the concentration of metal particles in order to obtain a surface that may either be soldered directly or which may be electro-plated.

In one example, the polymer may be provided with hydrophobic characteristics such that the semiconductor package may be protected from humidity.

While the disclosure has been illustrated and described with respect to one or more implementations, alterations and/or modifications may be made to the illustrated examples without departing from the spirit and scope of the appended claims. In particular regard to the various functions performed by the above described structures, the terms (including a reference to a “means”) used to describe such structures are intended to correspond, unless otherwise indicated, to any structure which performs the specified function of the described structure (e.g., that is functionally equivalent), even though not structurally equivalent to the disclosed structure which performs the function in the herein illustrated exemplary implementations of the disclosure.

Although specific aspects have been illustrated and described herein, it will be appreciated by those of ordinary skill in the art that a variety of alternate and/or equivalent implementations may be substituted for the specific aspects shown and described without departing from the scope of the disclosure. This application is intended to cover any adaptations or variations of the specific aspects discussed herein. Therefore, it is intended that this disclosure is limited only by the claims and the equivalents thereof.

What is claimed is:

1. A device, comprising:
a die; and
at least one of an encapsulant at least partly encapsulating the die and a carrier to which the die is attached, wherein the at least one of the encapsulant and the carrier comprises a thermoplastic polymer comprising metallic particles.

2. The device of claim 1, wherein a volumetric fill factor of the metallic particles in the thermoplastic polymer is chosen to provide a thermal conductivity of at least 20 W/(m*K).

3. The device of claim 1, wherein a volumetric fill factor of the metallic particles in the thermoplastic polymer is between 20% and 90%.

4. The device of claim 1, wherein the thermoplastic polymer is an amorphous thermoplastic polymer with a glass transition temperature of equal or greater than 260° C. or wherein the thermoplastic polymer is a crystalline or semi-crystalline thermoplastic polymer with a melting temperature of equal or greater than 260° C.

5. The device of claim 1, wherein the thermoplastic polymer comprises one or more polymers selected from a group comprising polyether ether ketone, polyamide-imide, polyethersulfone, polysulfone, polystyrene, polyphenylene sulfide and liquid-crystal polymer.

6. The semiconductor package of claim 1, wherein the metallic particles comprise copper particles.

7. The device of claim 1, wherein the encapsulant comprises metallic particles coated with an electrically insulating material.

8. The device of claim 7, wherein the electrically insulating material comprises an oxide of the metal.

9. The device of claim 1, wherein the metallic particles comprise copper fibers having a thickness of 30 micrometers to 120 micrometers.

10. The device of claim 1, wherein
the die comprises an active surface comprising electrical contacts, and a back surface opposite the active surface comprising a backside metallization, and
the carrier is directly attached to the die by injection molding.

11. The device of claim 1, wherein
the die comprises an active surface comprising electrical contacts, and a back surface opposite the active surface comprising a backside metallization,
the device further comprises an insulating material insulating side surfaces of the die, and an electrical contact provided over a surface of the device which is coplanar to the active surface of the die, and
a volumetric fill factor of the metallic particles in the thermoplastic polymer is chosen to provide an electrical conductivity of at least 10⁶ S/m.

12. The device of claim 1, wherein the die comprises an active surface and a backside surface opposite the active surface, wherein the metallic particles form a metallic surface over a surface of the device in a region of the encapsulant situated in a vicinity of the backside surface.

13. A semiconductor package, comprising:
a die; and
an encapsulant at least partly encapsulating the die, wherein the encapsulant comprises a polymer comprising metallic particles coated with an electrically insulating material.

14. The semiconductor package of claim 13, wherein the die comprises an active surface comprising electrical contacts, and wherein the active surface and a surface of the encapsulant are coplanar.

15. The semiconductor package of claim 14, wherein the electrically insulating material comprises an oxide of the metal.

16. A method for producing a semiconductor package, the method comprising:
providing an encapsulant material comprising a thermoplastic polymer including metallic particles;
placing a die into a mold; and
injection molding the semiconductor package by injecting the encapsulant material into the mold.

17. The method of claim 16, wherein the encapsulant material comprises a compounded material.

18. The method of claim 16, further comprising:
injection molding a carrier with the encapsulant material in the mold prior to placing the die into the mold; and
placing the die over or at least partly into the carrier when placing the die into the mold.

19. The method of claim 18, wherein the metallic particles in the encapsulant material are coated with an electrically insulating material except for the metallic particles in the encapsulant material used to form the carrier.

20. The method of claim 16, further comprising:
heating a surface of the semiconductor package, the heating at least partially changing a composition of the encapsulant material in a region near the surface to comprise essentially only the metallic particles.
